(19) United States
(12) Patent Application Publication
(10) Pub. No.: US 2017/0047915 A1
(43) Pub. Date: Feb. 16, 2017

(54) METHOD AND APPARATUS FOR SPECTRAL STITCHING USING REFERENCE CHANNEL AND PILOT TONES

(71) Applicant: Keysight Technologies, Inc., Minneapolis, MN (US)

(72) Inventors: Troels Studsgaard Nielsen, Aalborg (DK); Jan Verspecht, Londerzeel (BE); Joel P. Dunsmore, Sebastopol, CA (US)

(21) Appl. No.: 14/823,985

(22) Filed: Aug. 11, 2015

(51) Int. Cl. H03K 5/00; G01R 23/16

(52) U.S. Cl. CPC H03K 5/00006; G01R 23/16

(57) ABSTRACT

A system and method sequentially measure the amplitude and phase of an output signal of a device under test in each of two or more frequency ranges which together span the output signal spectrum, using a local oscillator (LO) signal whose frequency and phase change for each measurement. The measured phase of the output signal is adjusted for at least one of the frequency ranges to account for the change of phase in the LO signal from measurement of one frequency range to another frequency range, including applying to the measured phase a phase offset determined by measuring the phases of two pilot tones in the two or more frequency ranges, using the LO signal. The phase-adjusted measurements of the output signal in the two or more frequency ranges are stitched together to determine the amplitude and phase of the output signal across the output spectrum.

### BACKGROUND

In many situations, it is desired to be able to provide an accurate and complete measurement of one or more periodically modulated signals using a receiver or measurement device whose bandwidth is less than the bandwidth of the periodically modulated signal.

FIGS. 1A-C illustrate an example of this situation.

FIG. 1A shows an example frequency spectrum 110 of a periodically modulated input signal provided to a device under test (e.g., an amplifier) and an example frequency spectrum 120 of an output signal of the device under test. Here is illustrated an example where the bandwidth of the example frequency spectrum 120 of an output signal of the device under test is somewhat greater than the bandwidth of the spectrum 110 of a periodically modulated input signal, for example due to spectral regrowth in the device under test (e.g., an amplifier operating at least somewhat into compression). Of course it is understood that in general the bandwidth of the frequency spectrum of a periodically modulated input signal provided to a device under test and the bandwidth of the frequency spectrum of an output signal of the device under test may be the same as each other or different from each other.

FIG. 1B shows the example frequency spectrum 112 of the periodically modulated input signal, downconverted to baseband with a first mixing frequency (e.g., LO1), and the example frequency spectrum 122 of the output signal of the device under test, also downconverted to baseband with the first mixing frequency LO1, together with the spectrum of a filter 130 having the limited bandwidth R_{BW} of a receiver which is used to measure and characterize the periodically modulated input signal and the output signal of the device under test. Here it is assumed the bandwidth of the downconverted output signal of the device under test is S_{BW}>R_{BW}.

FIG. 1C shows the portion 114 of the spectrum of the periodically modulated input signal and the portion 124 of the spectrum of the output signal of the device under test which are actually able to be measured and characterized by the receiver with the limited bandwidth R_{BW}. As denoted in FIG. 1B, a portion 113 of the spectrum of the periodically modulated input signal, and a portion 123 of the spectrum of the output signal of the device under test, are not measured by the receiver because of the limited bandwidth R_{BW}.

Thus it would be desirable to provide a convenient and reliable method and system to measure and characterize a periodically modulated signal, and an output signal of a device under test (DUT) produced in response to the periodically modulated signal, using a receiver whose bandwidth is less than the bandwidth of the periodically modulated signal itself and/or the bandwidth of the output signal. It would further be desirable to provide such a system and method which can provide accurate measurements of phase sensitive characteristics, such as the error-vector-magnitude (EVM), for a DUT.

### SUMMARY

According to one aspect of the invention, a method comprises: receiving from a device under test (DUT) an output signal having an output signal spectrum; providing first and second pilot tones from corresponding first and second signal generators; sequentially converting portions of the output signal spectrum down to an intermediate frequency (IF) signal in a first IF channel by mixing the output signal with a local oscillator (LO) signal, wherein a frequency of the LO signal is changed for each sequential conversion, and measuring an amplitude and phase of the IF signal as a function of frequency for each of the sequentially converted portions of the output signal spectrum using a measurement device whose measurement bandwidth for any fixed frequency of the LO signal is less than a bandwidth of the output signal spectrum; during each sequential conversion, mixing the first and second pilot tones with the LO signal to produce converted first and second pilot tones, selecting frequencies of the first and second pilot tones such that for each sequential conversion the converted first and second pilot tones are spaced apart from each other within a second IF channel, wherein for each sequential conversion a frequency of one of the first and second pilot tones is maintained to be substantially the same as in an immediately preceding conversion, and a frequency of another one of the first and second pilot tones changes from the immediately preceding conversion, and wherein the one of the first and second pilot tones whose frequency is maintained to be substantially the same alternates from sequential conversion to sequential conversion; measuring a phase for each of the converted first and second pilot tones for each sequential conversion; adjusting the measured phase of the IF signal as a function of frequency for one or more of the sequentially converted portions of the output signal spectrum using the measured phases of the converted first and second pilot tones to produce phase-adjusted measurements of the IF signal; and stitching together the phase-adjusted measurements of the IF signal to produce a measurement of the amplitude and phase of the output signal across the output spectrum as a function of frequency.

In some embodiments, the first IF bandwidth of the first IF channel is approximately the same as a second IF bandwidth of the second IF channel.

In some embodiments, the amount by which the frequency of the LO signal is changed for each sequential conversion is about equal to a difference between the frequencies of the first and second pilot tones.

In some versions of these embodiments, the frequency of the one of the first and second pilot tones which does change from the immediately preceding conversion changes by about twice the amount by which the frequency of the LO signal is changed from the immediately preceding conversion.

In some embodiments, adjusting the measured phase of the IF signal as a function of frequency for one or more of the sequentially converted portions of the output signal spectrum using the measured phases of the converted first and second pilot tones comprises: for at least a current one of the sequential conversions, determining a phase adjustment to be applied to the measured phase of the IF signal as a function of frequency as a difference between: (1) the phase of the one of the first and second pilot tones which does change from the immediately preceding conversion, as measured for the current sequential conversion, and (2) the phase of the one of the first and second pilot tones which does change from the immediately preceding conversion, as measured for the immediately preceding conversion; and applying the determined phase adjustment to the measured phase of the IF signal as a function of frequency for the current sequential conversion.

In some embodiments, the method further comprises: receiving a second signal, having a second signal spectrum; during each sequential conversion of the portions of the output signal spectrum, sequentially converting portions of the second signal spectrum down to a second intermediate frequency (IF) signal in a third IF channel by mixing the second signal with the LO signal, and measuring an amplitude and phase of the second IF signal as a function of frequency for each of the sequentially converted portions of the second signal spectrum using a second measurement device whose measurement bandwidth for any fixed frequency of the LO signal is less than the bandwidth of the output signal; adjusting the measured phase of the second IF signal as a function of frequency for one or more of the sequentially converted portions of the second signal spectrum using the measured phases of the converted first and second pilot tones to produce phase-adjusted measurements of the second IF signal; and stitching together the phase-adjusted measurements of the second IF signal to produce a measurement of the amplitude and phase of the second signal across the second signal spectrum as a function of frequency, wherein the second signal is one of: an input signal which is also supplied to an input of the device under test and in response to which the device under test generates the output signal; a reflected signal produced from the input of the device under test; and a reflected signal produced from an output of the device under test.

In some embodiments, measuring the amplitude and phase of the IF signal as a function of frequency comprises: sampling the IF signal at a sample rate to produce samples of the IF signal, digitizing the samples of the IF signal, and performing a digital Fourier transform on the digitized samples of the IF signal.

In some versions of these embodiments the input signal supplied to the device under test in response to which the device under test generates the output signal is a periodic signal, and each sample is synchronized to occur at a same point in the periodic signal for each measurement of each portion of the output signal spectrum.

According to another aspect of the invention, a system is provided for measuring at least one characteristic of an output signal of a device under test (DUT), the output signal having an output signal spectrum. The system comprises: a local oscillator (LO) configured to generate an LO signal having an LO frequency; a first signal generator configured to generate a first pilot tone; a second signal generator configured to generate a second pilot tone; a first frequency converter configured to mix the output signal with the LO signal to produce an intermediate frequency (IF) signal in a first IF channel; a second frequency converter configured to mix the first and second pilot tones with the LO signal to produce converted first and second pilot tones within a second IF channel; a first measurement device connected to an output of the first frequency converter, the first measurement device having a measurement bandwidth which for any fixed frequency of the LO signal is less than a bandwidth of the output signal spectrum; a second measurement device connected to an output of the second frequency converter; and a controller. The controller is configured to control the system to: sequentially convert portions of the output signal spectrum down to the IF signal by: controlling the LO to change the LO frequency for each sequential conversion, and controlling the first and second signal generators during each sequential conversion to select frequencies of the first and second pilot tones such that during each sequential conversion the converted first and second pilot tones are spaced apart from each other within the second IF channel, wherein for each sequential conversion a frequency of one of the first and second pilot tones is maintained to be substantially the same as in an immediately preceding conversion, and a frequency of another one of the first and second pilot tones changes from the immediately preceding conversion, wherein the one of the first and second pilot tones whose frequency is maintained to be substantially the same alternates from sequential conversion to sequential conversion. The second measurement device is configured to measure a phase for each of the converted first and second pilot tones for each sequential conversion. The first measurement device is configured to measure an amplitude and phase of the IF signal as a function of frequency for each sequential conversion. The system is configured to adjust the measured phase of the IF signal for one or more of the sequentially converted portions of the output signal spectrum using the measured phases of the converted first and second pilot tones to produce phase-adjusted measurements of the IF signal, and to stitch together the phase-adjusted measurements of the IF signal to produce a measurement of the amplitude and phase of the output signal across the output signal spectrum as a function of frequency.

In some embodiments, a first IF bandwidth of the first IF channel is approximately the same as a second IF bandwidth of the second IF channel.

In some embodiments, the controller is configured to change the LO frequency for each sequential conversion by an amount about equal to a difference between the frequencies of the first and second pilot tones.

In some versions of these embodiments, the controller is configured to change the frequency of the one of the first and second pilot tones which does change from the immediately preceding conversion by about twice the amount by which the controller changes the frequency of the LO signal.

In some embodiments, the system is configured to adjust the measured phase of the IF signal as a function of frequency for one or more of the sequentially converted portions of the output signal spectrum using the measured phases of the converted first and second pilot tones by: for at least a current one of the sequential conversions, determining a phase adjustment to be applied to the measured phase of the IF signal as a function of frequency as a difference between: (1) the phase of the one of the first and second pilot tones which does change from the immediately preceding conversion, as measured for the current sequential conversion, and (2) the phase of the one of the first and second pilot tones which does change from the immediately preceding conversion, as measured for the immediately preceding conversion; and applying the determined phase adjustment to the measured phase of the IF signal as a function of frequency for the current sequential conversion.

In some embodiments, the system further comprises: a third frequency converter configured to mix a second signal to a second intermediate frequency (IF) signal in a third IF channel; and a third measurement device connected to an output of the third frequency converter and configured to measure an amplitude and phase of the second IF signal as a function of frequency for each of the sequential conversions, wherein the third measurement device has a measurement bandwidth which for any fixed frequency of the LO signal is less than the bandwidth of the output signal spectrum, wherein the second signal is one of: an input signal which is also supplied to an input of the device under test and in response to which the device under test generates the output signal; a reflected signal produced from the input of the device under test; and a reflected signal produced from an output of the device under test.

In some embodiments, the first frequency converter comprises: a first mixer having two inputs connected respectively to an output of the DUT and an output of the LO, and having an output; and a first low pass filter having an input connected to the output of the first mixer and having an output for outputting the IF signal.

In some embodiments, the first measurement device comprises: a sampler connected to the output of the first frequency converter and configured to sample the IF signal to produce IF samples; an analog-to-digital converter configured to digitize the IF samples; and a digital signal processor configured to perform a digital Fourier transform on the digitized IF samples and configured to obtain the amplitude and phase of the IF signal as a function of frequency.

According to still another aspect of the invention, a method comprises: receiving from a device under test an output signal having an output signal spectrum, the output signal spectrum comprising at least two frequency ranges which together span the output signal spectrum; sequentially measuring an amplitude and phase of the output signal as a function of frequency in each of the frequency ranges using a local oscillator (LO) signal whose frequency and phase are changed for each sequential measurement; adjusting a measured phase of the output signal as a function of frequency for at least one of the frequency ranges to account for the change of phase in the LO signal from measurement of one frequency range to measurement of a next frequency range to produce phase-adjusted measurements of the output signal; and stitching together the phase-adjusted measurements of the output signal as a function of frequency in each of the frequency ranges to produce a measurement of the amplitude and phase of the output signal across the output signal spectrum as a function of frequency, wherein adjusting the measured phase as a function of frequency for at least one of the frequency ranges to account for the change of phase in the LO signal includes applying to the measured phase a phase offset determined by measuring phases of two pilot tones using the LO signal as the frequency and phase of the LO signal change from measurement of one frequency range to measurement of the next frequency range, wherein the frequency of one of the two pilot tones is maintained to be substantially the same from measurement of one frequency range to measurement of a next frequency range, and the frequency of the other of the two pilot tones is changed from measurement of one frequency range to measurement of a next frequency range, and wherein the one of the two pilot tones whose frequency is maintained to be substantially the same and the other of the two pilot tones whose frequency is changed, alternate with each other from measurement to measurement.

In some embodiments, an amount by which the frequency of the LO signal is changed for each sequential conversion is about equal to a difference between the frequencies of the first and second pilot tones.

In some versions of these embodiments, the frequency of the one of the first and second pilot tones which does change from the immediately preceding measurement changes by about twice the amount by which the frequency of the LO signal is changed from the immediately preceding measurement.

In some embodiments, the method further comprises: receiving a second signal; sequentially measuring an amplitude and phase of the second signal as a function of frequency in each of the frequency ranges using the local oscillator (LO) signal whose frequency and phase are changed for each sequential measurement; adjusting a measured phase of the second signal as a function of frequency for at least one of the frequency ranges to account for the change of phase in the LO signal from measurement of one frequency range to measurement of a next frequency range to produce phase-adjusted measurements of the second signal; and stitching together the phase-adjusted measurements of the second signal as a function of frequency in each of the frequency ranges to produce a measurement of the amplitude and phase of the second signal as a function of frequency, wherein adjusting the measured phase of the second signal as a function of frequency for at least one of the frequency ranges to account for the change of phase in the LO signal includes applying the phase offset to the measured phase of the second signal, wherein the second signal is one of: an input signal which is also supplied to an input of the device under test and in response to which the device under test generates the output signal; a reflected signal produced from the input of the device under test; and a reflected signal produced from the output of the device under test.

### BRIEF DESCRIPTION OF THE DRAWINGS

The example embodiments are best understood from the following detailed description when read with the accompanying drawing figures. In fact, the dimensions may be arbitrarily increased or decreased for clarity of discussion. Wherever applicable and practical, like reference numerals refer to like elements.

FIGS. 1A, 1B and 1C illustrate an example of downconverting and measuring a spectrum with a measurement device having a limited bandwidth.

FIGS. 2A, 2B, 2C, 2D, 2E and 2F illustrate an example embodiment of a process of performing multiple downversions of overlapping portions of an input signal and output signal spectrum to measure the input and output signal with a measurement device having a limited bandwidth.

FIG. 3 illustrates an example embodiment of a measurement system for measuring a spectrum of a signal from a device under test, where the bandwidth of a measurement device of the measurement system is less than the bandwidth of the signal to be measured.

FIG. 4 illustrates an example embodiment of a method of measuring a spectrum of a signal from a device under test, where the bandwidth of the measurement device is less than the bandwidth of the signal to be measured, by stitching together measurements of four overlapping portions of the spectrum.

FIGS. 5A and 5B show a flowchart of a method of measuring a spectrum of a signal from a device under test, where the bandwidth of the measurement device is less than the bandwidth of the signal to be measured, by stitching together measurements of four overlapping portions of the spectrum.

FIG. 6 illustrates a series of operations which may be performed using the measurement system of FIG. 3 in one example embodiment of a method of measuring a spectrum of a signal from a device under test, where the bandwidth of the measurement device is less than the bandwidth of the signal to be measured.

### DETAILED DESCRIPTION

In the following detailed description, for purposes of explanation and not limitation, example embodiments disclosing specific details are set forth in order to provide a thorough understanding of an embodiment according to the present teachings. However, it will be apparent to one having ordinary skill in the art having had the benefit of the present disclosure that other embodiments according to the present teachings that depart from the specific details disclosed herein remain within the scope of the appended claims. Moreover, descriptions of well-known apparati and methods may be omitted so as to not obscure the description of the example embodiments. Such methods and apparati are clearly within the scope of the present teachings.

Unless otherwise noted, when a first device is said to be connected to a second device, this encompasses cases where one or more intermediate devices may be employed to connect the two devices to each other. However, when a first device is said to be directly connected to a second device, this encompasses only cases where the two devices are connected to each other without any intermediate or intervening devices. Similarly, when a signal is said to be coupled to a device, this encompasses cases where one or more intermediate devices may be employed to couple the signal to the device. However, when a signal is said to be directly coupled to a device, this encompasses only cases where the signal is directly coupled to the device without any intermediate or intervening devices.

As noted above, in some cases it is desired to be able to provide an accurate and complete measurement of one or more periodically modulated signals using a receiver whose bandwidth is less than the bandwidth of the periodically modulated signal. As an example, it may be desired to measure the error-vector-magnitude (EVM) of a power amplifier which is excited by a contiguously aggregated 5-carrier LTE-A signal having a bandwidth of 100 MHz using a receiver whose bandwidth R_{BW} is only 40 MHz. Because of spectral regrowth, the total bandwidth of the output signal of the amplifier could easily exceed 300 MHz.

If the output signal was simply downconverted to baseband and then processed by the receiver, the part of the spectrum of the signal which extends beyond the receiver's bandwidth of 40 MHz would be filtered out, and so the signal will not be measured or characterized correctly.

One technique to overcome this problem is spectral stitching. Spectral stitching involves performing multiple, separate, downversions of overlapping portions of the signal's spectrum using different downconversion mixing frequencies, and then stitching together the measurements of all of the overlapping portions in order to produce an overall measurement of the entire spectrum of the signal. The bandwidth of each of the portions is less than or equal to the bandwidth of the measurement receiver. For example, if the bandwidth of the signal's spectrum, S_{BW}, is 100 MHz, and the bandwidth of the measurement receiver, R_{BW}, is 30 MHz, then at least four separate downconversions for measuring at least four different portions of the signal spectrum are required. These four measurements can then be “spectrally stitched” together to produce a measurement of the entire signal spectrum of 100 MHz. In general, the number, N, of measurements of separate downconverted portions of the signal spectrum which must be performed is:

$$N = ⌈ \frac{{S}_{BW}}{{R}_{BW} - Δ} ⌉ , \qquad ( 1 )$$

where ┌ ┐ is the ceiling function, and wherein A is the minimum amount of overlap required for the adjacent spectral measurements.

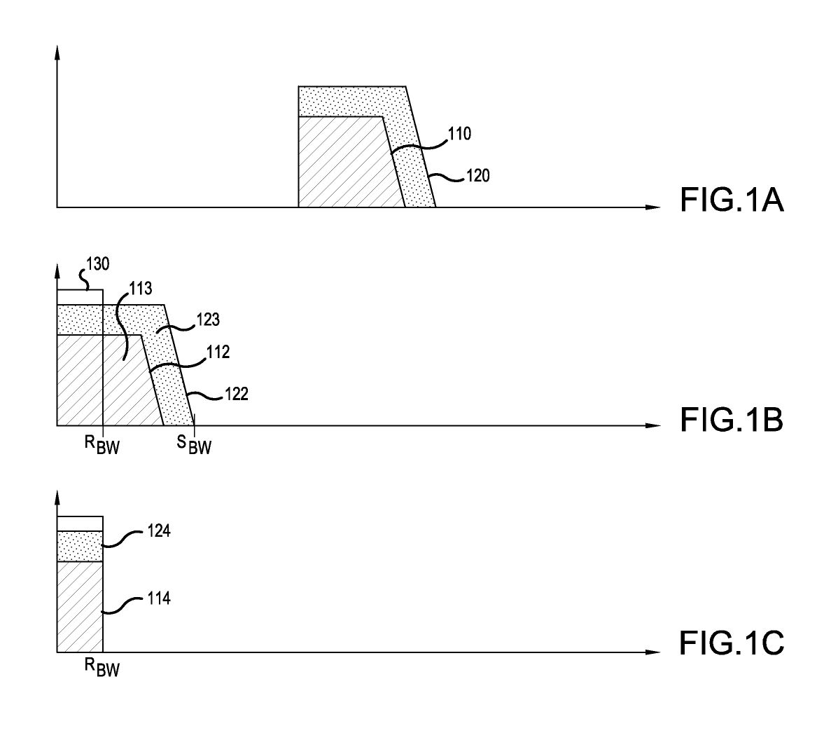

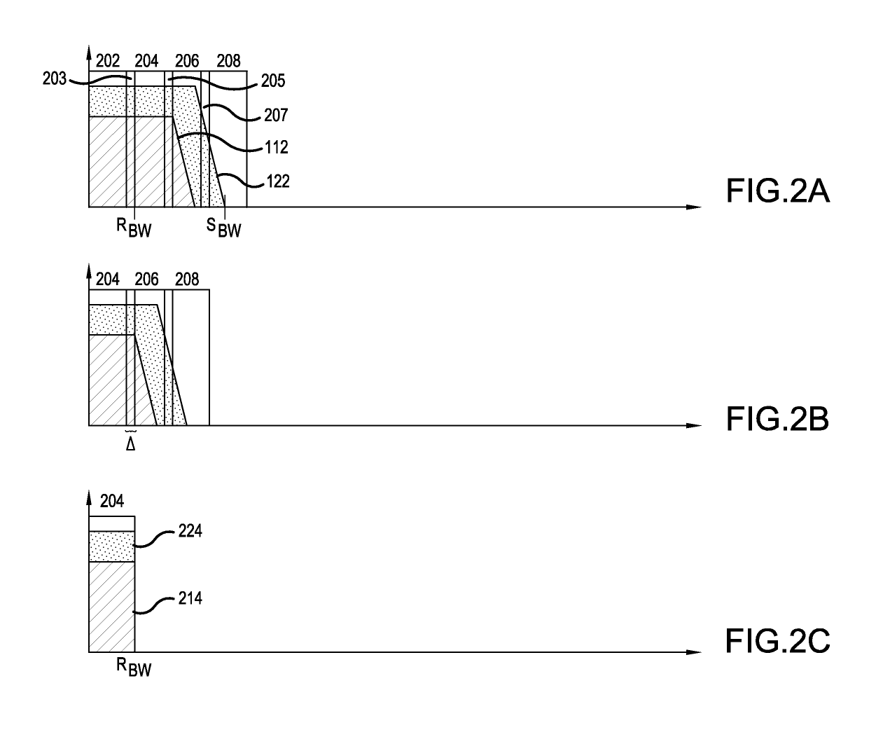

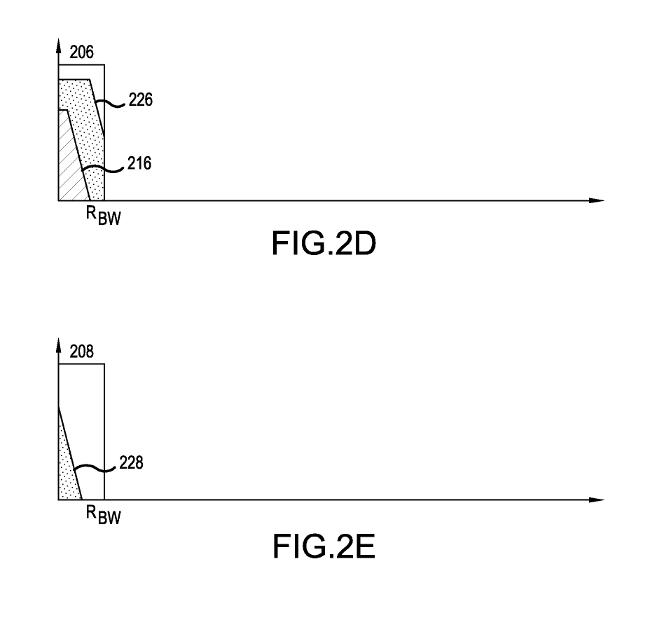

FIGS. 2A-2E illustrate an example embodiment of a process of performing multiple, separate, downversions of overlapping portions of an input signal spectrum and an output signal spectrum to measure the input and output signal with a measurement device having a limited bandwidth, that is a bandwidth which is less than the bandwidth of the signal(s) to be measured. In particular, FIGS. 2A-2E illustrate an example embodiment of a process of performing multiple, separate (sequential), downversions of overlapping portions of the example frequency spectrum 102 of a periodically modulated input signal which is supplied or provided to a device under test (DUT) (e.g., an amplifier) and the example frequency spectrum 104 of an output signal of the DUT which were discussed above with respect to FIGS. 1A-C.

FIG. 2A illustrates the frequency spectrum 112 of a periodically modulated input signal provided to a DUT (e.g., an amplifier), downconverted to baseband with a first mixing frequency (e.g., LO1), and the example frequency spectrum 122 of an output signal of the DUT, also downconverted to baseband with the first mixing frequency LO1, as was shown above in FIG. 1B.

FIG. 2A further illustrates how the downconverted frequency spectrum 122 of the output signal of the DUT can be divided into four overlapping portions or frequency ranges: 202, 204, 206 and 208, which each include an overlap region and which together span the frequency spectrum of the output signal. The overlap regions include: a first overlap region 203 for portions 202 and 204; a second overlap region 205 for portions 204 and 206; and a third overlap region 207 for portions 206 and 208. Of course the downconverted frequency spectrum 112 of the periodically modulated input signal also can be divided into overlapping portions, but for the sake of simplified description, the discussion below follows the downconverted frequency spectrum 122 of the output signal of the DUT.

As described above with respect to FIG. 1C above, when the downconverted frequency spectrum 122 of the output signal of the DUT is provided to a receiver with a limited bandwidth R_{BW}, then only the portion 202 is measured by the receiver.

However, as illustrated in FIGS. 2B-E, by repeating the downconversion process with different mixing frequencies, LO2, LO3 and LO4, each of the portions 204, 206 and 208 may be measured separately, and then all of the measured portions 202, 204, 206 and 208 may be stitched together as explained above to reproduce the original output signal frequency spectrum 122.

In particular, FIG. 2B illustrates the frequency spectrum 120 of the output signal of the DUT downconverted to baseband with a second mixing frequency (e.g., LO2), where here:

|LO2−LO1|=R_{BW}−Δ (2)

FIG. 2C then shows the portion 204 of the frequency spectrum 120 of the output signal of the DUT which is actually able to be measured and characterized by the receiver with the limited bandwidth R_{BW}.

Similarly, FIG. 2D shows the portion 206 of the frequency spectrum 120 of the output signal of the DUT which is actually able to be measured and characterized by the receiver with the limited bandwidth R_{BW} when the frequency spectrum 120 of the output signal of the DUT is downconverted to baseband with a third mixing frequency (e.g., LO3), where here:

↑LO3−LO2|=R_{BW}−Δ (3)

Finally, FIG. 2E shows the portion 208 of the frequency spectrum 120 of the output signal of the DUT which is actually able to be measured and characterized by the receiver with the limited bandwidth R_{BW} when the frequency spectrum 120 of the output signal of the DUT is downconverted to baseband with a fourth mixing frequency (e.g., LO4), where here:

|LO4=LO3|=R_{BW}−Δ (4)

As explained above, the frequency spectrum 120 of the output signal of the DUT can be reconstructed by spectrally stitching together the measurements of the overlapping portions 202, 204, 206 and 208.

However, in general there will be unknown phase shifts between the mixing frequencies LO1, LO2, LO3 and LO4 used for the four separate downconversions. In that case, although it is possible to reconstruct the amplitude of the output signal of the DUT as a function of frequency by stitching together the amplitude measurements of the four overlapping portions 202, 204, 206 and 208, reconstructing the phase of the output signal of the DUT as a function of frequency is not possible due to the above-mentioned unknown phase shifts being introduced into the measured phases of the four overlapping portions or frequency ranges 202, 204, 206 and 208. This prevents the measurement of phase-sensitive characteristics such as error-vector-magnitude (EVM).

Accordingly, it would be desirable to provide a system and method of spectral stitching which can further correct for unknown phase shifts between the mixing (LO) frequencies used for the various separate downconversions of the overlapping portions of the spectrum in the spectral stitching process.

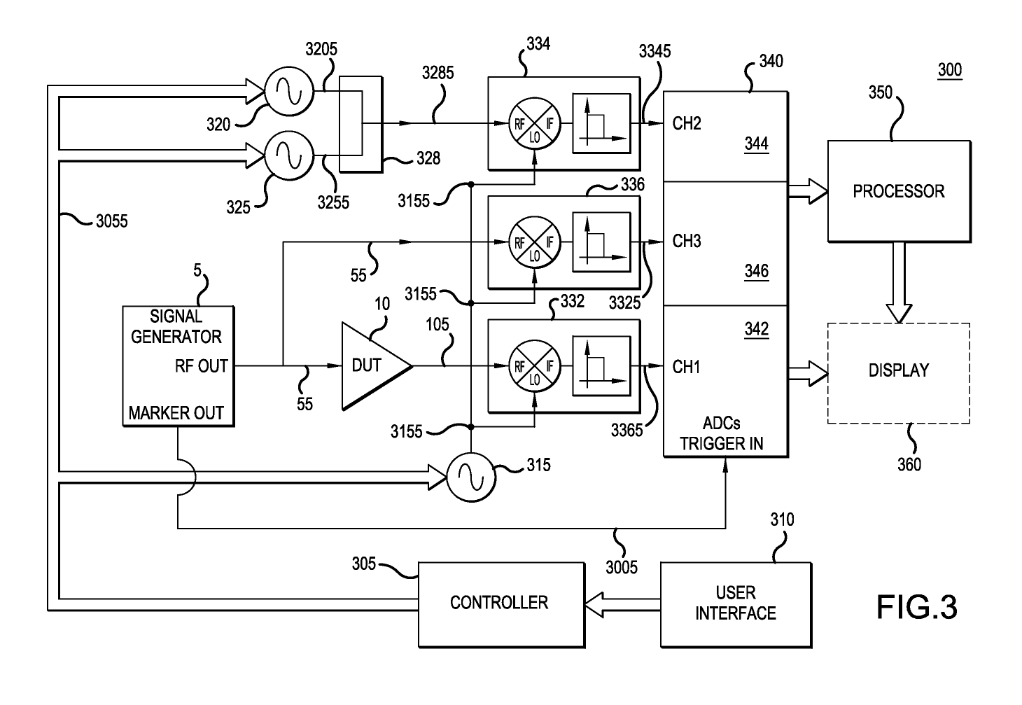

FIG. 3 illustrates an example embodiment of a measurement system 300 for measuring at least one characteristic, e.g., a spectrum, of a signal from a device under test, where the bandwidth of a measurement device in measurement system 300 is less than the bandwidth of the signal to be measured. Measurement system 300 includes: a controller 305; a user interface 310; a local oscillator 315; a first signal generator 320; a second signal generator 325; a signal combiner 328; a first frequency converter 332; a second frequency converter 334; a third frequency converter 336; a measurement instrument 340; a processor 350; and a display 360.

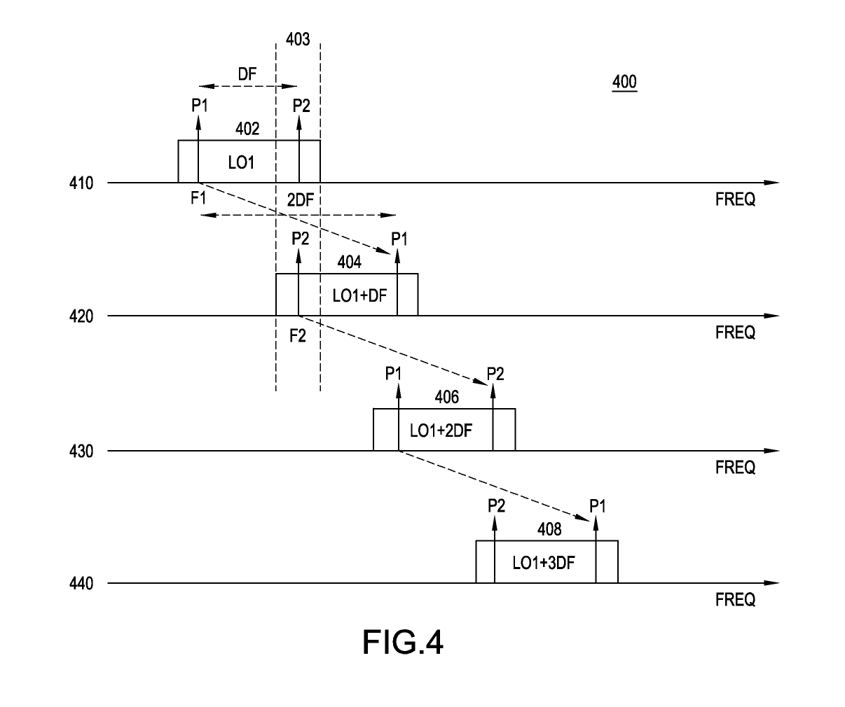

Controller 305 may include one or more processing elements (e.g., CPUs), memory (including volatile and/or nonvolatile memory), and a communication interface for communicating with local oscillator 315, first signal generator 320, and second signal generator 325. The memory may store therein instructions for causing the processor(s) to control operations of system 300, for example to perform various operations and methods described herein such as with respect to FIGS. 4-6 below. In some embodiments, controller 305 may communicate commands to local oscillator 315, first signal generator 320, and second signal generator 325 to set or adjust their output frequencies, amplitudes, etc. via a communication connection or bus 3055. Such communications may employ any of a variety of standard protocols such as General Purpose Interface Bus (GPIB)/IEEE-488, LAN eXtensions for Instrumentation (LXI), VME eXtensions for Instrumentation (VXI), PCI eXtensions for Instrumentation (PXI), universal serial bus (USB), FireWire, Ethernet, TCP/IP, etc.

In some embodiments, user interface 310 allows a user to program and/or set operating parameters for controller 305. For example, where controller 305 executes an algorithm which controls the output frequencies of local oscillator 315, first signal generator 320, and second signal generator 325, in some embodiments a user may enter the frequencies via user interface 310. User interface 310 may include any combination of well known input devices and output devices, such as a keyboard, mouse, trackball, keypad, pushbuttons, one or more display devices (which may include LCD readouts), etc.

In some embodiments, controller 305 and user interface 310 may be integrated into a single device, such as a computer, laptop, tablet, smartphone, etc.

Local oscillator 315, first signal generator 320, and second signal generator 325 may each comprise a programmable frequency generator generating a signal whose frequency is programmable, for example under control of controller 305 and/or via input controls integrated into the device.

Local oscillator 315 generates or produces a local oscillator (LO) signal 3155. First signal generator 320 generates or produces a first pilot tone 3205, and second signal generator 325 generates or produces a second pilot tone 3255.

Signal combiner 328 is configured to combine first pilot tone 3205 and second pilot tone 3255 to produce a combined reference channel signal 3285.

First frequency converter 332, second frequency converter 334 (also referred to as a reference frequency converter), and third frequency converter 336 each include a mixer and a low pass filter (LPF). Each of the mixers has two inputs, including a first input which receives LO signal 3155, and an output. The output of each mixer is connected to an input of the corresponding LPF, and the output of each LPF is at the output of the corresponding frequency converter. Beneficially, the bandwidths of the LPFs in first frequency converter 332, second frequency converter 334, and third frequency converter 336 may all be the same, or approximately the same, as each other.

First frequency converter 332 is also configured, or connected, to receive an output signal 105 of device under test (DUT) 10 (e.g., an amplifier). More specifically, output signal 105 is provided to the second input of the mixer of first frequency converter 332 and the mixer is configured to mix output signal 105 with LO signal 3155 to produce an intermediate frequency (IF) signal, also referred to herein as first IF signal, in a first IF channel 3325 at the output of the mixer. The input of the LPF receives the first IF signal, and the output of the LPF outputs the first IF signal at the output of first frequency converter 332.

Second frequency converter 334 (reference frequency converter) is configured, or connected, to receive reference channel signal 3285 including first pilot tone 3205 and second pilot tone 3255. More specifically, reference channel signal 3285 is provided to the second input of the mixer of second frequency converter 334 and the mixer is configured to mix reference channel signal 3285 with LO signal 3155 to produce converted first and second pilot tones in a second IF channel 3345 (also referred to as a reference channel) at the output of the mixer. The input of the LPF receives the converted first and second pilot tones, and the output of the LPF outputs the converted first and second pilot tones at the output of second frequency converter 334.

Third frequency converter 336 is configured, or connected, to receive a second signal and to mix the second signal with LO signal 3155 to produce a second intermediate frequency (IF) signal in a third IF channel 3365 at the output of the LPF. In the illustrated embodiment, the second signal is a periodically modulated input signal 55 provided to DUT 10 by periodic signal generator 5. However in other embodiments, the second signal may a reflected signal produced from the input of DUT 10, or a reflected signal produced from the output of DUT 10. More specifically, in the illustrated embodiment input signal 55 is provided to the second input of the mixer of third frequency converter 336 and the mixer is configured to mix input signal 55 with LO signal 3155 to produce the second IF signal in third IF channel 3365 at the output of the mixer. The input of the LPF receives the second IF signal, and the output of the LPF outputs the second IF signal at the output of third frequency converter 336.

Measurement instrument includes a first measurement device 342, a second measurement device 344 (also referred to as a reference measurement device), and a third measurement device 346.

First measurement device 342, second measurement device 344, and third measurement device 346 may each comprise a sampler, an analog-to-digital converter (ADC) and memory. In some embodiments, memory may be shared among first measurement device 342, second measurement device 344, and third measurement device 346. In particular first measurement device 342 is configured to sample and digitize first IF channel 3325 and produce a plurality of data samples at an operating frequency of the sampler and ADC. Second measurement device 344 is configured to sample and digitize second IF channel 3345 and produce a plurality of data samples at an operating frequency of the sampler and ADC. Third measurement device 346 is configured to sample and digitize third IF channel 3365 and produce a plurality of data samples at an operating frequency of the sampler and ADC. The data samples may be stored in memory for subsequent processing by measurement instrument 340 and/or processor 350. Beneficially, the operating frequencies of all of the samplers/ADCs, and the bandwidths of first measurement device 342, second measurement device 344, and third measurement device 346 may all be the same as each other. Beneficially, the bandwidths of the LPFs in first frequency converter 332, second frequency converter 334, and third frequency converter 336 may be selected to match the operating bandwidths of the ADCs in first measurement device 342, second measurement device 344, and third measurement device 346. In some embodiments, first measurement device 342, second measurement device 344, and third measurement device 346 each may include a digital signal processor which is configured to perform a Fourier transform (e.g., a digital Fourier transform) on data samples output by the ADC.

Processor 350 may include one or more processing elements (e.g., CPUs) and memory, including volatile and/or nonvolatile memory, which may store instructions to be executed by the processing element(s). Processor 350 is configured to process the data samples from first measurement device 342, second measurement device 344, and third measurement device 346 to provide measurements of output signal 105 and the second signal (e.g., input signal 55) provided to third measurement device 346. In some embodiments, processor 350 may include one or more digital signal processors configured to perform a Fourier transform (e.g., a digital Fourier transform) on data samples from each of the first measurement device 342, second measurement device 344, and third measurement device 346. In some embodiments, processor 350 may process the data samples from first measurement device 342 and second measurement device 344 to stitch together phase-adjusted measurements of the first IF signal in first IF channel 3325 to produce a measurement of the amplitude and phase of output signal 105 across the output spectrum as a function of frequency.

In some embodiments, processor 350 and controller 305 may be combined, and may share processing resources, including memory, one or more processors, and/or user interface 310.

Display 360 is configured to display waveforms generated by processor 350 from ADC data produced by measurement instrument 340. In some embodiments, display 360 may be combined with, or part of, user interface 310.

Operations of system 300 for measuring or characterizing one or more signals related to DUT 10 will now be described.

Here it is assumed that the signal bandwidth S_{BW} of output signal 105 is less than the receiver bandwidth R_{BW} of first measurement device 342, which may be limited by the maximum conversion rate of an ADC which is included in first measurement device 342. Furthermore, it is assumed here that the signal bandwidth S_{BW} of input signal 55 is also less than the receiver bandwidth R_{BW} of third measurement device 346. It is further assumed that input signal 55 is a periodically modulated signal. It is also assumed that signal generator 5, local oscillator 315, first signal generator 320, and second signal generator are all frequency locked or synchronized to a common master reference frequency (e.g., 10 MHz), for example provided by a master reference frequency generator (not shown in FIG. 3) to which all of these components are connected. Finally, it is assumed that any systematic phase dispersions in the IF channels are corrected for by system 300, for example by means of a system calibration procedure.

In operation, input signal 55 and output signal 105 are each converted to a corresponding IF signal at a lower frequency in a corresponding IF channel 3325/3365 by first and third frequency converters 332 and 336, respectively. In particular, first and third frequency converters 332 and 336 mix input signal 55 and output signal 105, respectively, with LO signal 3155, and then low pass filter the output of the mixer. The IF signals in IF channels 3325 and 3365 are then sampled and digitized by a corresponding pair of ADCs in first and second measurement devices 342 and 346 to produce ADC data. Processor 350 converts the ADC data to frequency domain date by performing a digital Fourier transform (DFT) on the ADC data.

The ADCs in first and second measurement devices 342 and 346 are synchronized with each other, and are further synchronized to the start of the modulation period of input signal 55. One method to realize the synchronization is by using a “marker out” signal 3005 output by signal generator 5 and provided to measurement instrument 340, which uses it as a trigger signal for the ADCs. Other methods can be used to realize the synchronization. Beneficially, each sample made by the samplers and ADCs may be synchronized to occur at a same point in the period of periodic input signal 55 for each measurement of each portion (e.g., 202, 204, 206 and 208) of frequency spectrum 122 of output signal 105.

In order to measure the complete spectra of input signal 55 and output signal 105, the spectra will be divided into two or more overlapping portions or frequency ranges (e.g., 202, 204, 206 and 208) which are each individually measured and then stitched together, as described above.

However it is a challenge, as described above, is to reconstruct the phase of input signal 55 and output signal 105 across their bandwidth from the measured phase of each portion of the spectrum. Every one of these measurements of a different portion of the spectrum of output signal 105 or input signal 55 will be made with a different LO frequency, and in general when the LO frequency is changed, an arbitrary and unknown phase shift occurs in LO signal 3155. When the phase measurements of the different portions are stitched together, these phase shifts produce errors in the phase measurement of the overall spectrum unless they are corrected. It should be noted that the same LO signal 3155 is used by both frequency converters 332 and 336.

System 300 addresses this challenge by measuring the phase shifts of LO signal 3155, when the LO frequency is changed from one measurement to the next, through the use of second frequency converter 334 (reference frequency converter), second measurement device 344 (reference measurement device), and the first and second pilot tones 3205 and 3255 generated by first and second signal generators 320 and 325. System 300 (e.g., by means of processor 350): (1) adjusts the measured phase of the IF signal(s) in IF channels 3325/3365 as a function of frequency for one or more of the sequentially converted portions of the output signal spectrum using by applying to the measured phase a phase offset determined from measured phases of the converted first and second pilot tones 3205 and 3255 to account for the change of phase in LO signal 3155 from measurement of one portion (or frequency range) to measurement of a next portion (or frequency range), to thereby produce phase-adjusted measurements of the IF signal; and (2) stitches together the phase-adjusted measurements of the IF signal(s) to produce a measurement of the amplitude and phase of input signal 55 across the input spectrum, and/or output signal 105 across the output spectrum, as a function of frequency.

A concrete example will now be provided to better illustrate various aspects of embodiments of the systems and methods disclosed herein. In this example, the overall frequency spectrum of the signal being measured is divided into N=4 portions which are measured separately or sequentially, and stitched together to produce an overall spectrum of a signal which is being measured. However it should be understood that in general N may be any integer greater than 1.

FIG. 4 illustrates an example embodiment of a method 400 of measuring a spectrum of a signal from a device under test, where the bandwidth of the measurement device is less than the bandwidth of the signal to be measured, by stitching together measurements of four overlapping portions of the spectrum.

In an operation 410, when measuring a first portion of the spectrum (e.g., first portion 202 in FIG. 2A), the LO frequency of LO signal 3115 is set (e.g., by controller 305) to LO1. The frequency of first pilot tone 3205 (also referred to as P1) is set (e.g., by controller 305) to a frequency F1 in the lower part of second IF channel 3345 (which mirrors first IF channel 3325 and third IF channel 3365), in particular a region of the first portion which does not overlap with a second portion of the spectrum (e.g., second portion 204 in FIGS. 2A-2C) to be measured next. Meanwhile, the frequency of second pilot tone 3255 (also referred to as P2) is set (e.g., by controller 305) to a frequency F2 in the upper part of second IF channel 3345, in particular a region (e.g., overlap region 203) of the first portion which overlaps with a second portion of the spectrum (e.g., second portion 204 in FIGS. 2A-2C) to be measured next. The difference between the frequencies F2 and F1 is denoted as DF. Measurement instrument 340 measures: the first IF signal in first IF channel 3325 representing the downconverted first portion of output signal 105; the second IF signal in third IF channel 3365 representing the downconverted first portion of input signal 55; and the downconverted first and second pilot tones P1 and P2 of reference channel signal 3285 in second IF channel 3345. Measurement instrument 340 or processor 350 applies a phase correction or fixed phase shift to all of the measured spectra, where the fixed phase shift equals the negative of the measured phase (PH₁(1)) of first pilot tone P1. The phase-adjusted spectra will be the first portion of the reconstructed stitched spectra. Meanwhile, the phase-adjusted value of the measured phase (PH₁(2)) of second pilot tone P2, may be stored in memory as T1. Here T1=PH₁(2)−PH₁(1). Note that this first phase shift equal to the negative of the measured phase (PH₁(1)) is not necessary and may be omitted in some embodiments. It is included only in the described embodiment to reflect a more general implementation. The phase-adjusted data for the first portion of the spectrum of input signal 55 and the phase-adjusted for the first portion of the spectrum of output signal 105 may be stored in memory.

Next, in an operation 420, the LO frequency of LO signal 3115 is set (e.g., by controller 305) to LO2=LO1+DF. The frequency of first pilot tone P1 3205 is increased (e.g., by controller 305) by 2*DF to a frequency F1+2*DF which is now in the upper part of second IF channel 3345 (which mirrors first IF channel 3325 and third IF channel 3365), in particular a region (e.g., overlap region 205) of the second portion which overlaps with a third portion of the spectrum (e.g., third portion 206 in FIGS. 2B and 2D) to be measured next. Meanwhile, the frequency of second pilot tone P2 (F2) 3255 is maintained to be substantially the same as in the immediately preceding conversion or operation 410. Here, when we say that the frequency of a pilot tone is maintained to be substantially the same as in an immediately preceding conversion, this indicates that the frequency remains the same except for any minor frequency drift within the tolerances of second signal generator 325. For example, controller 305 may not issue any command in operation 420 to second signal generator 325 to change the frequency of second pilot tone P2, and accordingly second signal generator 325 continues to output second pilot tone P2 whose frequency F2 is not changed with respect to immediately preceding operation 410. As explained below, by maintaining the frequency of second pilot tone P2 unchanged between operations 410 and 420, a reference point can be established for factoring out an effect caused by a change in the phase of LO signal 3155 which occurs in general between operations 410 and 420 due to the output frequency of local oscillator 315 being changed or reprogrammed, for example by controller 305. Measurement instrument 340 measures: the first IF signal in first IF channel 3325 representing the downconverted second portion of output signal 105; the second IF signal in third IF channel 3365 representing the downconverted second portion of input signal 55; and the downconverted first and second pilot tones P1 and P2 of reference channel signal 3285 in second IF channel 3345. Measurement instrument 340 or processor 350 applies a fixed phase shift to all of the measured spectra, where the fixed phase shift equals T1 minus the measured phase (PH₂(2)) of second pilot tone P2. The phase-adjusted spectra will be the second portion of the reconstructed stitched spectra. Meanwhile, the phase-adjusted value of the measured phase (PH₂(1)) of first pilot tone P1 may be stored in memory as T2. Here T2=PH₂(1)−PH₂(2)+PH₁(2)−PH₁(1). The phase-adjusted data for the second portion of the spectrum of input signal 55 and the phase-adjusted data for the second portion of the spectrum of output signal 105 may be stored in memory.

Next, in an operation 430, the LO frequency of LO signal 3115 is set (e.g., by controller 305) to LO3=LO1+2*DF. The frequency of second pilot tone P2 is increased (e.g., by controller 305) by 2*DF to a frequency F2+2DF which is now in the upper part of second IF channel 3345 (which mirrors first IF channel 3325 and third IF channel 3365), in particular a region (e.g., overlap region 207) of the third portion which overlaps with a fourth portion of the spectrum (e.g., fourth portion 208 in FIGS. 2B and 2E) to be measured next. Meanwhile, the frequency of first pilot tone P1 (F1+2*DF) is maintained at substantially the same frequency as in the preceding operation 420. Measurement instrument 340 measures: the first IF signal in first IF channel 3325 representing the downconverted third portion of output signal 105; the second IF signal in third IF channel 3365 representing the downconverted third portion of input signal 55; and the downconverted first and second pilot tones P1 and P2 of reference channel signal 3285 in second IF channel 3345. Measurement instrument 340 or processor 350 applies a fixed phase shift to all of the measured spectra, where the fixed phase shift equals T2 minus the measured phase (PH₃(1)) of first pilot tone P1. The phase-adjusted spectra will be the third portion of the reconstructed stitched spectra. Meanwhile, the phase-adjusted value of the measured phase (PH₃(2)) of second pilot tone P2 may be stored in memory as T3. Here T3=PH₃(2)−PH₃(1)+PH₂(1)−PH₂(2)+PH₁(2)−PH₁(1). The phase-adjusted data for the third portion of the spectrum of input signal 55 and the phase-adjusted data for the third portion of the spectrum of output signal 105 may be stored in memory.

Next, in an operation 440, the LO frequency of LO signal 3115 is set (e.g., by controller 305) to LO4=LO1+3+*DF. The frequency of first pilot tone P1 is increased (e.g., by controller 305) by 2*DF to a frequency F1+4*DF which is now in the upper part of second IF channel 3345 (which mirrors first IF channel 3325 and third IF channel 3365. Meanwhile, the frequency of second pilot tone P2 (F2+2*DF) is maintained at substantially the same frequency as in the preceding operation 430. Measurement instrument 340 measures: the first IF signal in first IF channel 3325 representing the downconverted fourth portion of output signal 105; the second IF signal in third IF channel 3365 representing the downconverted fourth portion of input signal 55; and the downconverted first and second pilot tones P1 and P2 of reference channel signal 3285 in second IF channel 3345. Measurement instrument 340 or processor 350 applies a fixed phase shift T4 to all of the measured spectra, where the fixed phase shift T4 equals T3 minus the measured phase (PH₄(2)) of second pilot tone P2. The phase-adjusted spectra will be the fourth portion of the reconstructed stitched spectra. The phase-adjusted data for the fourth portion of the spectrum of input signal 55 and the phase-adjusted data for the fourth portion of the spectrum of output signal 105 may be stored in memory.

In general, this procedure is repeated until all N portions of the spectra of input signal 55 and output signal 105 are measured. The phase-adjusted data for all N portions of the spectrum of input signal 55 are stitched together to produce the input signal spectrum, and the phase-adjusted data for all N portions of the spectrum of output signal 105 are stitched together to produce the output signal spectrum.

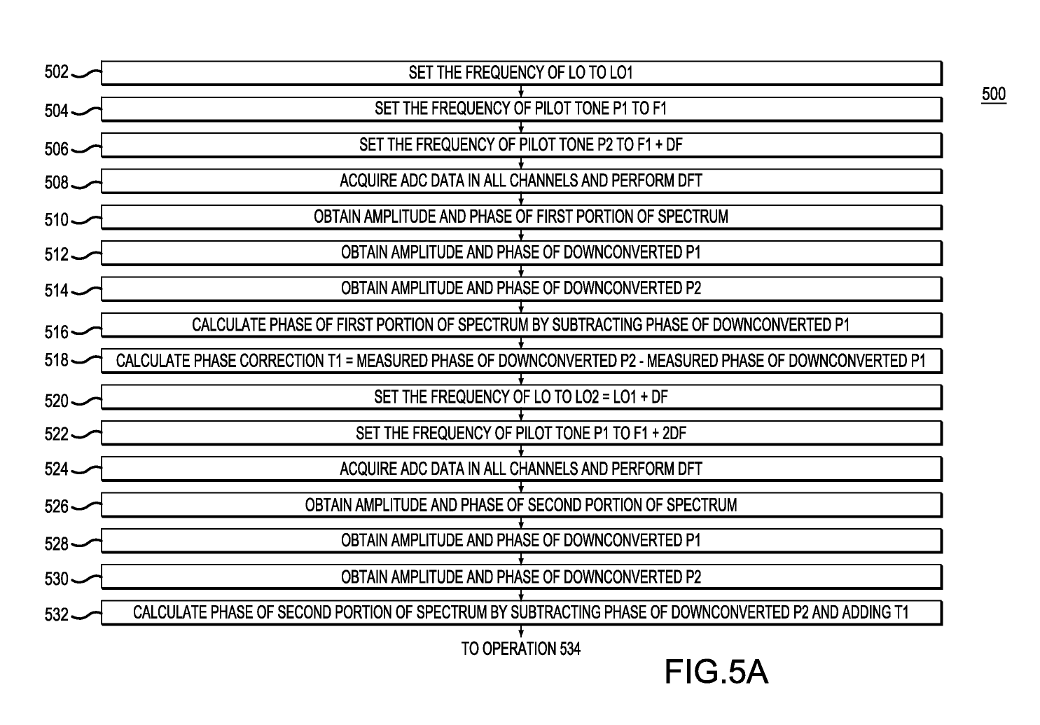

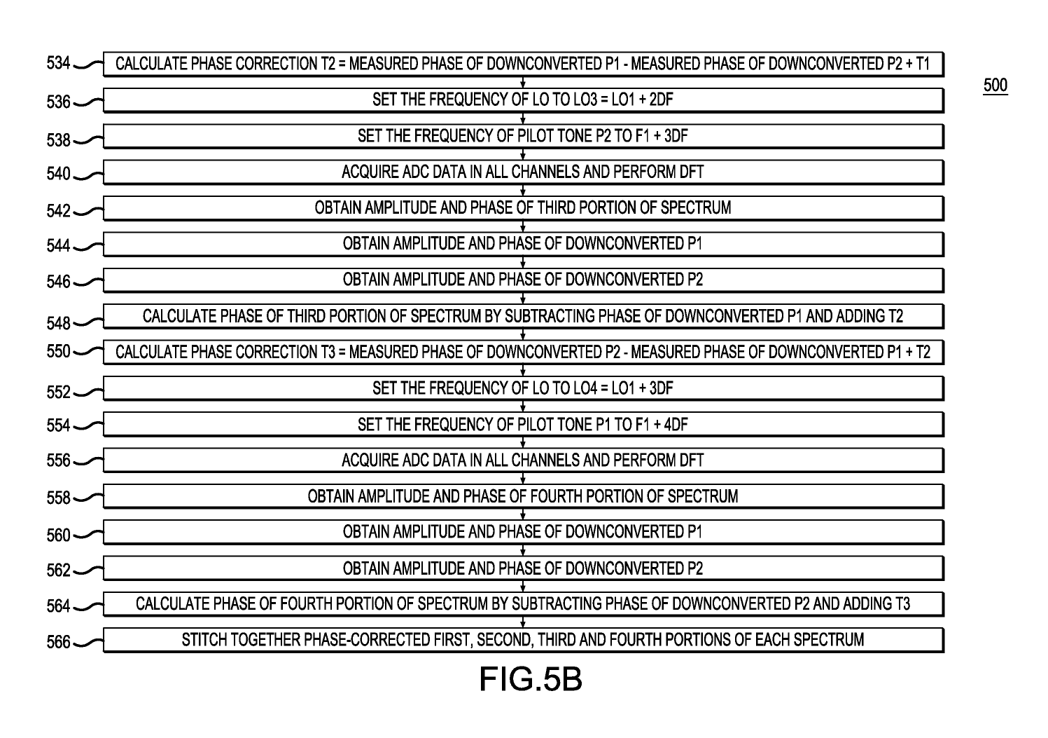

FIGS. 5A and 5B show a flowchart of a method 500 of measuring a spectrum of a signal from a device under test, where the bandwidth of the measurement device is less than the bandwidth of the signal to be measured, by stitching together measurements of four overlapping portions of the spectrum. In particular, the method 500 comprises an embodiment of detailed steps for the method 400 shown in FIG. 4.

An operation 502 includes setting the frequency of LO signal 3155 to LO1. In some embodiments, this operation may be performed by controller 305 sending a command to local oscillator 315 via communication bus 3055.

An operation 504 includes setting the frequency of pilot tone P1 to F1. In some embodiments, this operation may be performed by controller 305 sending a command to first signal generator 320 via communication bus 3055.

An operation 506 includes setting the frequency of pilot tone P2 to F1+DF. In some embodiments, this operation may be performed by controller 305 sending a command to second signal generator 325 via communication bus 3055.

An operation 508 includes acquiring ADC data for all IF channels, and performing a digital Fourier transform (DFT) on the ADC data. For example, the ADC data for output signal 105 may be obtained by first measurement device 332 sampling the first IF signal in first IF channel 3325 at a sample rate, and digitizing the sample. In various embodiments, measurement instrument 340 or processor 350 may perform the digital Fourier transform on the digitized samples of the first IF signal (also referred to as digitized IF samples).

An operation 510 includes obtaining the amplitude and phase of the first portion of the spectrum for each signal being measured. In various embodiments, operation 510 may be performed by measurement instrument 340 and/or processor 350.

An operation 512 includes obtaining the amplitude and phase of the downconverted pilot tone P1. In some embodiments, operation 512 may be performed by measurement instrument 340 and/or processor 350.

An operation 514 includes obtaining the amplitude and phase of the downconverted pilot tone P2. In some embodiments, operation 514 may be performed by measurement instrument 340 and/or processor 350.

An operation 516 includes calculating the adjusted or corrected phase of the first portion of the spectrum of each signal which is being measured, by subtracting the phase of the downconverted pilot tone P1 from the measured phase of the first portion of the spectrum to produce a phase-adjusted measurement of the first portion of the spectrum of each signal which is being measured. In some embodiments, operation 516 may be performed by measurement instrument 340 and/or processor 350.

An operation 518 includes calculating a phase correction T1=measured phase of the downconverted pilot tone P2−measured phase of the downconverted pilot tone P1. In some embodiments, operation 518 may be performed by measurement instrument 340 and/or processor 350.

An operation 520 includes setting the frequency of LO signal 3155 to LO2=LO1+DF. In some embodiments, this operation may be performed by controller 305 sending a command to local oscillator 315 via communication bus 3055.

An operation 522 includes setting the frequency of pilot tone P1 to F1+2DF. In some embodiments, this operation may be performed by controller 305 sending a command to first signal generator 320 via communication bus 3055.

An operation 524 includes acquiring ADC data for all IF channels, and performing a discrete Fourier transform. For example, the ADC data for output signal 105 may be obtained by first measurement device 332 sampling the first IF signal in first IF channel 3325 at a sample rate, and digitizing the sample. In some embodiments, measurement instrument 340 or processor 350 performs a digital Fourier transform on the digitized samples of the first IF signal.

An operation 526 includes obtaining the amplitude and phase of the second portion of the spectrum for each signal being measured. In some embodiments, operation 526 may be performed by measurement instrument 340 and/or processor 350.

An operation 528 includes obtaining the amplitude and phase of the downconverted pilot tone P1. In some embodiments, operation 528 may be performed by measurement instrument 340 and/or processor 350.

An operation 530 includes obtaining the amplitude and phase of the downconverted pilot tone P2. In some embodiments, operation 530 may be performed by measurement instrument 340 and/or processor 350.

An operation 532 includes calculating the adjusted or corrected phase of the second portion of the spectrum of each signal which is being measured, by subtracting the phase of the downconverted pilot tone P2 from the measured phase of the second portion of the spectrum, and adding T1 to produce a phase-adjusted measurement of the second portion of the spectrum of each signal which is being measured.

An operation 534 includes calculating a phase correction T2=Measured Phase of the downconverted pilot tone P1−Measured Phase of the downconverted pilot tone P2+T1.

An operation 536 includes setting the frequency of LO signal 3155 to LO3=LO1+2DF. In some embodiments, this operation may be performed by controller 305 sending a command to local oscillator 315 via communication bus 3055.

An operation 538 includes setting the frequency of pilot tone P2 to F1+3DF. In some embodiments, this operation may be performed by controller 305 sending a command to second signal generator 325 via communication bus 3055.

An operation 540 includes acquiring ADC data for all IF channels, and performing a discrete Fourier transform. For example, the ADC data for output signal 105 may be obtained by first measurement device 332 sampling the first IF signal in first IF channel 3325 at a sample rate, and digitizing the sample. In some embodiments, measurement instrument 340 or processor 350 performs a digital Fourier transform on the digitized samples of the first IF signal.

An operation 542 includes obtaining the amplitude and phase of the third portion of the spectrum of each signal which is being measured. In some embodiments, operation 542 may be performed by measurement instrument 340 and/or processor 350.

An operation 544 includes obtaining the amplitude and phase of the downconverted pilot tone P1. In some embodiments, operation 544 may be performed by measurement instrument 340 and/or processor 350.

An operation 546 includes obtaining the amplitude and phase of the downconverted pilot tone P2. In some embodiments, operation 546 may be performed by measurement instrument 340 and/or processor 350.

An operation 548 includes calculating the adjusted or corrected phase of the third portion of the spectrum of each signal being measured by subtracting the phase of the downconverted pilot tone P1 from the measured phase of the third portion of the spectrum and adding T2 to produce a phase-adjusted measurement of the third portion of the spectrum of each signal which is being measured.

An operation 550 includes calculating a phase correction T3=Measured Phase of the downconverted pilot tone P2−Measured Phase of the downconverted pilot tone P1+T2.

An operation 552 includes setting the frequency of LO signal 3155 to LO4=LO1+3DF. In some embodiments, this operation may be performed by controller 305 sending a command to local oscillator 315 via communication bus 3055.

An operation 554 includes setting the frequency of pilot tone P1 to F1+4DF. In some embodiments, this operation may be performed by controller 305 sending a command to first signal generator 320 via communication bus 3055.

An operation 556 includes acquiring ADC data for all IF channels, and performing a discrete Fourier transform. For example, the ADC data for output signal 105 may be obtained by first measurement device 332 sampling the first IF signal in first IF channel 3325 at a sample rate, and digitizing the sample. In some embodiments, measurement instrument 340 or processor 350 performs a digital Fourier transform on the digitized samples of the first IF signal.

An operation 558 includes obtaining the amplitude and phase of the fourth portion of the spectrum of each signal which is being measured. In some embodiments, operation 558 may be performed by measurement instrument 340 and/or processor 350.

An operation 560 includes obtaining the amplitude and phase of the downconverted pilot tone P1. In some embodiments, operation 560 may be performed by measurement instrument 340 and/or processor 350.

An operation 562 includes obtaining the amplitude and phase of the downconverted pilot tone P2. In some embodiments, operation 562 may be performed by measurement instrument 340 and/or processor 350.

An operation 564 includes calculating the adjusted or corrected phase of the fourth portion of the spectrum by subtracting the phase of the downconverted pilot tone P2 from the measured phase of the fourth portion of the spectrum and adding T3 to produce a phase-adjusted measurement of the fourth portion of the spectrum of each signal which is being measured.

An operation 566 includes stitching together the phase-adjusted first, second, third and fourth portions of the spectra as obtained above to reconstruct the overall spectra of each of the signals which is being measured.

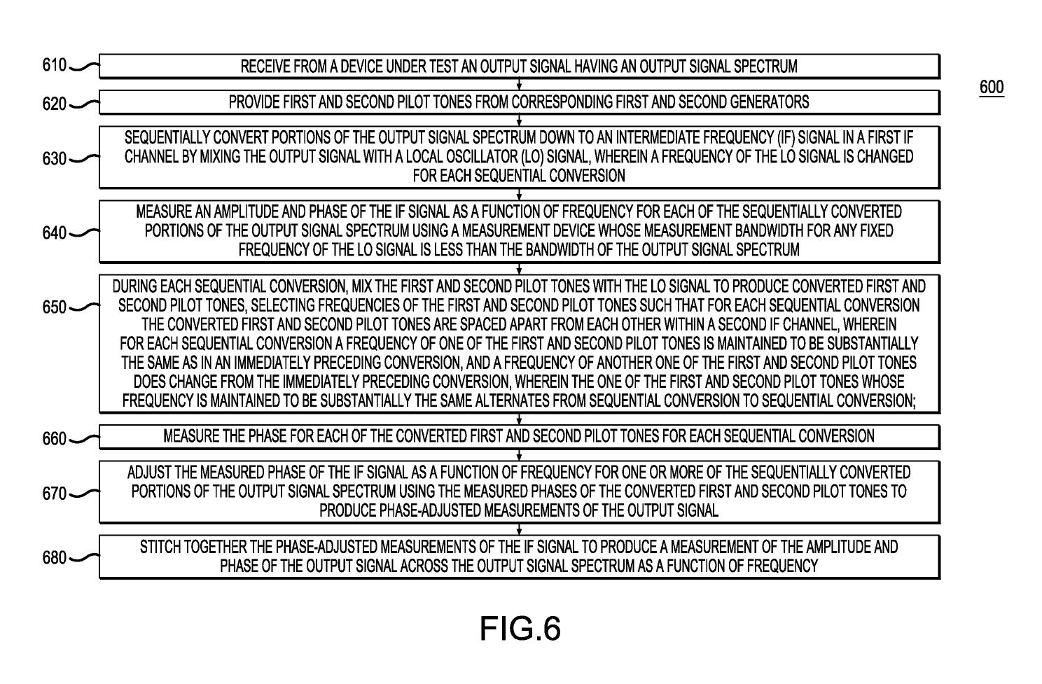

FIG. 6 illustrates a series of operations which may be performed using the system 300 of FIG. 3 in one example embodiment of a method 600 of measuring a spectrum of a signal from a device under test, where the bandwidth of the measurement device is less than the bandwidth of the signal to be measured.

An operation 610 may include receiving from device under test (DUT) 10 output signal 105 having an output signal spectrum (e.g., frequency spectrum 120).

An operation 620 may include providing first and second pilot tones 3205 and 3255 from corresponding first and second signal generators 320 and 325.

An operation 630 may include first frequency converter 332 sequentially converting portions (e.g., portions 202, 204, 206 and 208) of the output signal spectrum down to an intermediate frequency (IF) signal in first IF channel 3325 by mixing output signal 105 with local oscillator (LO) signal 3155, wherein a frequency of the LO signal is changed for each sequential conversion. Beneficially, the amount by which the frequency of LO signal 3155 is changed for each sequential conversion is about equal to a difference between the frequencies of the first and second pilot tones 3205 and 3255.

An operation 640 may measure an amplitude and phase of the IF signal in first IF channel 3325 as a function of frequency for each of the sequentially converted portions of the output signal spectrum using first measurement device 342 whose measurement bandwidth for any fixed frequency of the LO signal is less than the bandwidth of the output signal spectrum. Beneficially, measuring the amplitude and phase of the IF signal as a function of frequency includes: sampling the IF signal at a sample rate, digitizing the samples of the IF signal, and performing a digital Fourier transform on the digitized samples of the IF signal.

An operation 650 may include, during each sequential conversion, second frequency converter 334 mixing first and second pilot tones 3205 and 3255 with LO signal 3155 to produce converted first and second pilot tones, wherein the frequencies of first and second pilot tones 3205 and 3255 are selected such that for each sequential conversion, the converted first and second pilot tones are spaced apart from each other within second IF channel 3345, wherein for each sequential conversion a frequency of one of first and second pilot tones (3205 or 3255) is maintained to be substantially the same as in an immediately preceding conversion, and a frequency of the other one of first and second pilot tones (3255 or 3205) changes from the immediately preceding conversion, and wherein the one of the first and second pilot tones 3205 and 3255 whose frequency is maintained to be substantially the same alternates from sequential conversion to sequential conversion. Beneficially, the IF bandwidth of first IF channel 3325 is approximately the same as the IF bandwidth of second IF channel 3345. Beneficially, the frequency of the one of first and second pilot tones (3205 or 3255) which does change from the immediately preceding conversion changes by about twice the amount by which the frequency of LO signal 3155 is changed from the immediately preceding measurement.

An operation 660 may include second measurement device 334 measuring a phase for each of the converted first and second pilot tones for each sequential conversion.

An operation 670 may include processor 350 adjusting the measured phase of the IF signal as a function of frequency for one or more of the sequentially converted portions of the output signal spectrum using the measured phases of the converted first and second pilot tones to produce phase-adjusted measurements of the IF signal in first IF channel 3325. Beneficially, adjusting the measured phase of the IF signal as a function of frequency for one or more of the sequentially converted portions of the output signal spectrum using the measured phases of the converted first and second pilot tones 3205 and 3255 includes: for at least a current one of the sequential conversions, determining a phase adjustment to be applied to the measured phase of the IF signal as a function of frequency as a difference between: (1) the phase of the one of the first and second pilot tones (3205 or 3255) which does change from the immediately preceding conversion, as measured for the current sequential conversion, and (2) the phase of the one of the first and second pilot tones (3255 or 3205) which does change from the immediately preceding conversion, as measured for an immediately preceding sequential conversion; and applying the determined phase adjustment to the measured phase of the IF signal as a function of frequency for the current sequential conversion. Beneficially, the phase-adjusted measurements of the IF signal represent phase-adjusted measurements of output signal 105 from which the IF signal in first IF channel 3325 was produced.

An operation 680 may include processor 350 stitching together the phase-adjusted measurements of the IF signal to produce a measurement of the amplitude and phase of the output signal across the output spectrum as a function of frequency.

The method 600 may include other operations, for example operations related to characterizing a second signal (e.g., input signal 55 in response to which DUT 10 generates output signal 105; a reflected signal produced from the input of the DUT 10; a reflected signal produced from the output of DUT 10; etc.) in addition to output signal 105, for example by performing similar operations to operations for 610, 630, 640, 670 and 680, for the second signal.

While example embodiments are disclosed herein, one of ordinary skill in the art appreciates that many variations that are in accordance with the present teachings are possible and remain within the scope of the appended claims. The invention therefore is not to be restricted except within the scope of the appended claims.

1. A method comprising:
receiving from a device under test (DUT) an output signal having an output signal spectrum;
providing first and second pilot tones from corresponding first and second signal generators;
sequentially converting portions of the output signal spectrum down to an intermediate frequency (IF) signal in a first IF channel by mixing the output signal with a local oscillator (LO) signal, wherein a frequency of the LO signal is changed for each sequential conversion, and measuring an amplitude and phase of the IF signal as a function of frequency for each of the sequentially converted portions of the output signal spectrum using a measurement device whose measurement bandwidth for any fixed frequency of the LO signal is less than a bandwidth of the output signal spectrum;
during each sequential conversion, mixing the first and second pilot tones with the LO signal to produce converted first and second pilot tones, selecting frequencies of the first and second pilot tones such that for each sequential conversion the converted first and second pilot tones are spaced apart from each other within a second IF channel, wherein for each sequential conversion a frequency of one of the first and second pilot tones is maintained to be substantially the same as in an immediately preceding conversion, and a frequency of another one of the first and second pilot tones changes from the immediately preceding conversion, and wherein the one of the first and second pilot tones whose frequency is maintained to be substantially the same alternates from sequential conversion to sequential conversion;
measuring a phase for each of the converted first and second pilot tones for each sequential conversion;
adjusting the measured phase of the IF signal as a function of frequency for one or more of the sequentially converted portions of the output signal spectrum using the measured phases of the converted first and second pilot tones to produce phase-adjusted measurements of the IF signal; and
stitching together the phase-adjusted measurements of the IF signal to produce a measurement of the amplitude and phase of the output signal across the output signal spectrum as a function of frequency.

2. The method of claim 1, wherein a first IF bandwidth of the first IF channel is approximately the same as a second IF bandwidth of the second IF channel.

3. The method of claim 1, wherein an amount by which the frequency of the LO signal is changed for each sequential conversion is about equal to a difference between the frequencies of the first and second pilot tones.

4. The method of claim 3, wherein the frequency of the one of the first and second pilot tones which does change from the immediately preceding conversion changes by about twice the amount by which the frequency of the LO signal is changed from the immediately preceding conversion.

5. The method of claim 1, wherein adjusting the measured phase of the IF signal as a function of frequency for one or more of the sequentially converted portions of the output signal spectrum using the measured phases of the converted first and second pilot tones comprises:
for at least a current one of the sequential conversions, determining a phase adjustment to be applied to the measured phase of the IF signal as a function of frequency as a difference between: (1) the phase of the one of the first and second pilot tones which does change from the immediately preceding conversion, as measured for the current sequential conversion, and (2) the phase of the one of the first and second pilot tones which does change from the immediately preceding conversion, as measured for the immediately preceding conversion; and
applying the determined phase adjustment to the measured phase of the IF signal as a function of frequency for the current sequential conversion.

6. The method of claim 1, further comprising:
receiving a second signal, having a second signal spectrum;
during each sequential conversion of the portions of the output signal spectrum, sequentially converting portions of the second signal spectrum down to a second intermediate frequency (IF) signal in a third IF channel by mixing the second signal with the LO signal, and measuring an amplitude and phase of the second IF signal as a function of frequency for each of the sequentially converted portions of the second signal spectrum using a second measurement device whose measurement bandwidth for any fixed frequency of the LO signal is less than the bandwidth of the output signal spectrum;
adjusting the measured phase of the second IF signal as a function of frequency for one or more of the sequentially converted portions of the second signal spectrum using the measured phases of the converted first and second pilot tones to produce phase-adjusted measurements of the second IF signal; and
stitching together the phase-adjusted measurements of the second IF signal to produce a measurement of the amplitude and phase of the second signal across the second signal spectrum as a function of frequency,
wherein the second signal is one of: an input signal which is also supplied to an input of the device under test and in response to which the device under test generates the output signal; a reflected signal produced from the input of the device under test; and a reflected signal produced from an output of the device under test.

7. The method of claim 1, wherein measuring the amplitude and phase of the IF signal as a function of frequency comprises:
sampling the IF signal at a sample rate to produce samples of the IF signal,
digitizing the samples of the IF signal, and
performing a digital Fourier transform on the digitized samples of the IF signal.

8. The method of claim 7, wherein an input signal supplied to the device under test in response to which the device under test generates the output signal is a periodic signal, and wherein each sample is synchronized to occur at a same point in the periodic signal for each measurement of each portion of the output signal spectrum.

9. A system for measuring at least one characteristic of an output signal of a device under test (DUT), the output signal having an output signal spectrum, the system comprising:
a local oscillator (LO) configured to generate an LO signal having an LO frequency;
a first signal generator configured to generate a first pilot tone;
a second signal generator configured to generate a second pilot tone;
a first frequency converter configured to mix the output signal with the LO signal to produce an intermediate frequency (IF) signal in a first IF channel;
a second frequency converter configured to mix the first and second pilot tones with the LO signal to produce converted first and second pilot tones within a second IF channel;
a first measurement device connected to an output of the first frequency converter, the first measurement device having a measurement bandwidth which for any fixed frequency of the LO signal is less than a bandwidth of the output signal spectrum;
a second measurement device connected to an output of the second frequency converter;
a controller configured to control the system to sequentially convert portions of the output signal spectrum down to the IF signal by:
controlling the LO to change the LO frequency for each sequential conversion, and
controlling the first and second signal generators during each sequential conversion to select frequencies of the first and second pilot tones such that during each sequential conversion the converted first and second pilot tones are spaced apart from each other within the second IF channel, wherein for each sequential conversion a frequency of one of the first and second pilot tones is maintained to be substantially the same as in from an immediately preceding conversion, and a frequency of another one of the first and second pilot tones changes from the immediately preceding conversion, wherein the one of the first and second pilot tones whose frequency is maintained to be substantially the same alternates from sequential conversion to sequential conversion,
wherein the second measurement device is configured to measure a phase for each of the converted first and second pilot tones for each sequential conversion,
wherein the first measurement device is configured to measure an amplitude and phase of the IF signal as a function of frequency for each sequential conversion,
wherein the system is configured to adjust the measured phase of the IF signal for one or more of the sequentially converted portions of the output signal spectrum using the measured phases of the converted first and second pilot tones to produce phase-adjusted measurements of the IF signal, and to stitch together the phase-adjusted measurements of the IF signal to produce a measurement of the amplitude and phase of the output signal across the output signal spectrum as a function of frequency.

10. The system of claim 9, wherein a first IF bandwidth of the first IF channel is approximately the same as a second IF bandwidth of the second IF channel.

11. The system of claim 9, wherein the controller is configured to change the LO frequency for each sequential conversion by an amount about equal to a difference between the frequencies of the first and second pilot tones.

12. The system of claim 11, wherein the controller is configured to change the frequency of the one of the first and second pilot tones which does change from the immediately preceding conversion by about twice the amount by which the controller changes the frequency of the LO signal.

13. The system of claim 9, wherein the system is configured to adjust the measured phase of the IF signal as a function of frequency for one or more of the sequentially converted portions of the output signal spectrum using the measured phases of the converted first and second pilot tones by:
for at least a current one of the sequential conversions, determining a phase adjustment to be applied to the measured phase of the IF signal as a function of frequency as a difference between: (1) the phase of the one of the first and second pilot tones which does change from the immediately preceding conversion, as measured for the current sequential conversion, and (2) the phase of the one of the first and second pilot tones which does change from the immediately preceding conversion, as measured for the immediately preceding conversion; and
applying the determined phase adjustment to the measured phase of the IF signal as a function of frequency for the current sequential conversion.

14. The system of claim 9, further comprising:
a third frequency converter configured to mix a second signal to a second intermediate frequency (IF) signal in a third IF channel; and
a third measurement device connected to an output of the third frequency converter and configured to measure an amplitude and phase of the second IF signal as a function of frequency for each of the sequential conversions, wherein the third measurement device has a measurement bandwidth which for any fixed frequency of the LO signal is less than the bandwidth of the output signal spectrum,
wherein the second signal is one of: an input signal which is also supplied to an input of the device under test and in response to which the device under test generates the output signal; a reflected signal produced from the input of the device under test; and a reflected signal produced from an output of the device under test.

15. The system of claim 9, wherein the first frequency converter comprises:
a first mixer having two inputs connected respectively to an output of the DUT and an output of the LO, and having an output; and
a first low pass filter having an input connected to the output of the first mixer and having an output for outputting the IF signal.

16. The system of claim 9, wherein the first measurement device comprises:
a sampler connected to the output of the first frequency converter and configured to sample the IF signal to produce IF samples;
an analog-to-digital converter configured to digitize the IF samples; and
a digital signal processor configured to perform a digital Fourier transform on the digitized IF samples and configured to obtain the amplitude and phase of the IF signal as a function of frequency.

17. A method, comprising:
receiving from a device under test an output signal having an output signal spectrum, the output signal spectrum comprising at least two frequency ranges which together span the output signal spectrum;
sequentially measuring an amplitude and phase of the output signal as a function of frequency in each of the frequency ranges using a local oscillator (LO) signal whose frequency and phase are changed for each sequential measurement;
adjusting a measured phase of the output signal as a function of frequency for at least one of the frequency ranges to account for the change of phase in the LO signal from measurement of one frequency range to measurement of a next frequency range to produce phase-adjusted measurements of the output signal; and
stitching together the phase-adjusted measurements of the output signal as a function of frequency in each of the frequency ranges to produce a measurement of the amplitude and phase of the output signal across the output signal spectrum as a function of frequency,
wherein adjusting the measured phase as a function of frequency for at least one of the frequency ranges to account for the change of phase in the LO signal includes applying to the measured phase a phase offset determined by measuring phases of two pilot tones using the LO signal, as the frequency and phase of the LO signal change from measurement of one frequency range to measurement of the next frequency range,
wherein the frequency of one of the two pilot tones is maintained to be substantially the same from measurement of one frequency range to measurement of a next frequency range, and the frequency of the other of the two pilot tones is changed from measurement of one frequency range to measurement of a next frequency range, and
wherein the one of the two pilot tones whose frequency is maintained to be substantially the same, and the other of the two pilot tones whose frequency is changed, alternate with each other from measurement to measurement.

18. The method of claim 17, wherein an amount by which the frequency of the LO signal is changed for each sequential conversion is about equal to a difference between the frequencies of the first and second pilot tones.

19. The method of claim 18, wherein the frequency of the one of the first and second pilot tones which does change from the immediately preceding measurement changes by about twice the amount by which the frequency of the LO signal is changed from the immediately preceding measurement.

20. The method of claim 17, further comprising:
receiving a second signal;
sequentially measuring an amplitude and phase of the second signal as a function of frequency in each of the frequency ranges using the local oscillator (LO) signal whose frequency and phase are changed for each sequential measurement;
adjusting a measured phase of the second signal as a function of frequency for at least one of the frequency ranges to account for the change of phase in the LO signal from measurement of one frequency range to measurement of a next frequency range to produce phase-adjusted measurements of the second signal; and
stitching together the phase-adjusted measurements of the second signal as a function of frequency in each of the frequency ranges to produce a measurement of the amplitude and phase of the second signal as a function of frequency,
wherein adjusting the measured phase of the second signal as a function of frequency for at least one of the frequency ranges to account for the change of phase in the LO signal includes applying the phase offset to the measured phase of the second signal, and
wherein the second signal is one of: an input signal which is also supplied to an input of the device under test and in response to which the device under test generates the output signal; a reflected signal produced from the input of the device under test; and a reflected signal produced from the output of the device under test.
